(19) United States
(12) Patent Application Publication
(10) Pub. No.: US 2014/0217437 A1
(43) Pub. Date: Aug. 7, 2014

(54) LIGHT EMITTING APPARATUS AND MANUFACTURING METHOD THEREOF

(71) Applicant: SAMSUNG ELECTRONICS CO., LTD., Suwon-si (KR)

(72) Inventor: Jae Yoon KIM, Gyeonggi-do (KP)

(73) Assignee: SAMSUNG ELECTRONICS CO., LTD., Suwon-si (KR)

(21) Appl. No.: 13/762,144

(22) Filed: Feb. 7, 2013

(51) Int. Cl. H01L 33/50

(52) U.S. Cl. CPC H01L 33/50
USPC 257/98; 438/27

(57) ABSTRACT

The present application provides for a method for manufacturing a light emitting apparatus. The method includes mounting light emitting elements on a substrate and applying a resin containing phosphors to form wavelength conversion units covering the light emitting elements on the substrate. Portions of the wavelength conversion unit are removed between the light emitting elements. Regions of the substrate are diced, from which the wavelength conversion unit have been removed, to separate the plurality light emitting elements into individual light emitting elements.

### CROSS-REFERENCE TO RELATED APPLICATIONS

This application claims the priority to Korean Patent Application No. 10-2012-0012165 filed on Feb. 7, 2012, in the Korean Intellectual Property Office, the disclosure of which is incorporated herein by reference.

### TECHNICAL FIELD

The present application relates to a light emitting apparatus and a manufacturing method thereof.

### BACKGROUND

Recently, a light emitting diode (LED), emitting light according to an electrical signal applied thereto, has commonly been used as a light emitting source in various electronic products, as well as mobile communications terminals such as a mobile phone, a personal digital assistant (PDA), and the like.

An LED is a type of light emitting element capable of implementing light of various colors through the use of compound semiconductor materials such as GaAs, AlGaAs, GaN, InGaInP, or the like.

An LED may emit red light, blue right, green light, or ultraviolet light, respectively, according to a composition thereof, and white light may be implemented therefrom by mixing red light, blue light, and green light emitted from respective LEDs.

Such an LED may be manufactured by mixing a phosphor material for wavelength conversion with a resin such as o silicon, or the like, and applying the same. However, a problem exists when a wavelength conversion unit is formed on a surface of the LED and does not have a uniform height. This non-uniformity may occur during the method of mixing a phosphor material with a resin and applying the same. In particular, in the case of LEDs manufactured through a mass-production process, a height dispersion of wavelength conversion units thereof falls short of the requirements.

Accordingly, a need exists to manufacture a light emitting apparatus that includes a wavelength conversion unit having a uniform height to meet production specification requirements.

### SUMMARY

In manufacturing an apparatus including light emitting elements having a wavelength conversion unit formed on a surface thereof through mass-production, it is desirable to provide a method for manufacturing light emitting apparatus including a wavelength conversion unit having a uniform height to thus allow for a height dispersion thereof in order to satisfy production requirements.

In particular, in the case of a light emitting element having a horizontal structure and a flip chip-type light emitting element, it is desirable to provide a method for forming a light emitting apparatus including a wavelength conversion unit having a uniform height by applying a wavelength conversion material to an upper portion of the light emitting element in a wafer unit (or on a wafer level).

According to an aspect of the present application, there is provided a method for manufacturing a light emitting apparatus. The method includes mounting light emitting elements on a substrate and applying a resin containing phosphors to form wavelength conversion units covering the light emitting elements on the substrate. Portions of the wavelength conversion unit are removed between the light emitting elements. Regions of the substrate are diced, from which the portions of the wavelength conversion unit have been removed, to separate the light emitting elements into individual light emitting elements.

The mounting of the light emitting elements may include connecting electrode pads formed on upper surfaces of the light emitting elements to electrodes formed on the substrate with wires.

The light emitting elements may be mounted on the substrate such that lower surfaces thereof having electrode pads formed thereon are in contact with the electrodes of the substrate.

In the forming of the wavelength conversion unit, a resin containing one or more types of phosphors may be commonly applied to the plurality of light emitting elements through a printing method.

The portions of the wavelength conversion unit may be removed by using a laser lift-off process or blade grooving.

The method may further include forming lenses on upper surfaces of the light emitting elements having the wavelength conversion units formed thereon, after removing the wavelength conversion unit formed between the plurality of light emitting elements.

According to another aspect of the present application, there is provided a method for manufacturing a light emitting apparatus. The method includes mounting light emitting elements on a substrate and applying a resin containing phosphors to form wavelength conversion units covering the light emitting elements on the substrate. Portions of the wavelength conversion unit are between the light emitting elements. Upper portions of the substrate are filled, from which the portions of the wavelength conversion unit have been removed, with a resin to form partition walls. The partition walls and the substrate under the partition walls are diced to separate the light emitting elements into individual light emitting elements.

The mounting of the light emitting elements may include connecting electrode pads formed on upper surfaces of the plurality of light emitting elements to electrodes formed on the substrate with wires.

The light emitting elements may be mounted on the substrate such that lower surfaces thereof having electrode pads formed thereon are in contact with the electrodes of the substrate.

In the forming of the wavelength conversion unit, a resin containing one or more types of phosphors may be commonly applied to the light emitting elements through a printing process.

In the removing of the portions of the wavelength conversion unit formed between the plurality of light emitting elements, the portions of the wavelength conversion unit may be removed by using a laser lift-off process or blade grooving.

The white resin may include one or more materials among polyphthalamide (PPA), a liquid crystal polymer (LCP), polycarbonate (PC), bismaleimide trizine (BT), and silicon.

The method may further include polishing upper surfaces of the wavelength conversion unit and the partition walls, after the forming of the partition walls by filling the upper portions of the substrate, from which the portions of the wavelength conversion unit have been removed, with the resin.

According to another aspect of the present application, there is provided a method for manufacturing a light emitting apparatus. The method includes forming partition walls confining peripheral regions of light emitting elements to mounting portions in which the light emitting elements are to be mounted on a substrate. Light emitting elements are mounted on the mounting portions. A resin containing phosphors is applied to inner sides of the partition walls to form wavelength conversion units covering the light emitting elements. The partition walls are removed and the portions of the substrate are diced, from which the partition walls were removed, to separate the light emitting elements into individual light emitting elements.

The mounting of the light emitting elements may include connecting electrode pads formed on upper surfaces of the light emitting elements to electrodes formed on the substrate with wires.

The light emitting elements may be mounted on the substrate such that lower surfaces thereof having electrode pads formed thereon are in contact with the electrodes of the substrate.

The partition walls may be formed by coating the substrate with a photosensitive polymer and then performing photolithography thereon.

The partition walls may be formed by using a dry film laminate (DFL) method.

The method may further include: forming lenses on upper surfaces of the light emitting elements having the wavelength conversion unit formed thereon, after removing the partition walls.

According to another aspect of the present application, there is provided a light emitting apparatus. The apparatus includes a substrate; light emitting elements mounted on the substrate; and a wavelength conversion unit formed on upper and lateral surfaces of the light emitting elements. A wavelength of light emitted from the light emitting elements is converted.

Additional advantages and novel features will be set forth in part in the description which follows, and in part will become apparent to those skilled in the art upon examination of the following and the accompanying drawings or may be learned by production or operation of the examples. The advantages of the present teachings may be realized and attained by practice or use of various aspects of the methodologies, instrumentalities and combinations set forth in the detailed examples discussed below.

### BRIEF DESCRIPTION OF THE DRAWINGS

The drawing figures depict one or more implementations in accord with the present teachings, by way of example only, not by way of limitation. In the figures, like reference numerals refer to the same or similar elements.

FIGS. 1 through 7 are views illustrating a method for manufacturing a light emitting apparatus according to an example of the present application;

FIGS. 8 through 13 are views illustrating a method for manufacturing a light emitting apparatus according to another example of the present application;

FIGS. 14 through 17 are views illustrating a method for manufacturing a light emitting apparatus according to another example of the present application; and

FIGS. 18 through 22 are views illustrating a method for manufacturing a light emitting apparatus according to another example of the present application.

### DETAILED DESCRIPTION

In the following detailed description, numerous specific details are set forth by way of examples in order to provide a thorough understanding of the relevant teachings.

However, it should be apparent to those skilled in the art that the present teachings may be practiced without such details. In other instances, well known methods, procedures, components, and/or circuitry have been described at a relatively high-level, without detail, in order to avoid unnecessarily obscuring aspects of the present teachings.

A light emitting apparatus and a method for manufacturing a light emitting apparatus according to examples of the present application will now be described in detail with reference to the accompanying drawings. The application may, however, be embodied in many different forms and should not be construed as being limited to the examples set forth herein. Rather, these examples are provided so that this disclosure will be thorough and complete, and will fully convey the scope of the application to those skilled in the art.

In the drawings, the shapes and dimensions of elements may be exaggerated for clarity, and the same reference numerals will be used throughout to designate the same or like components.

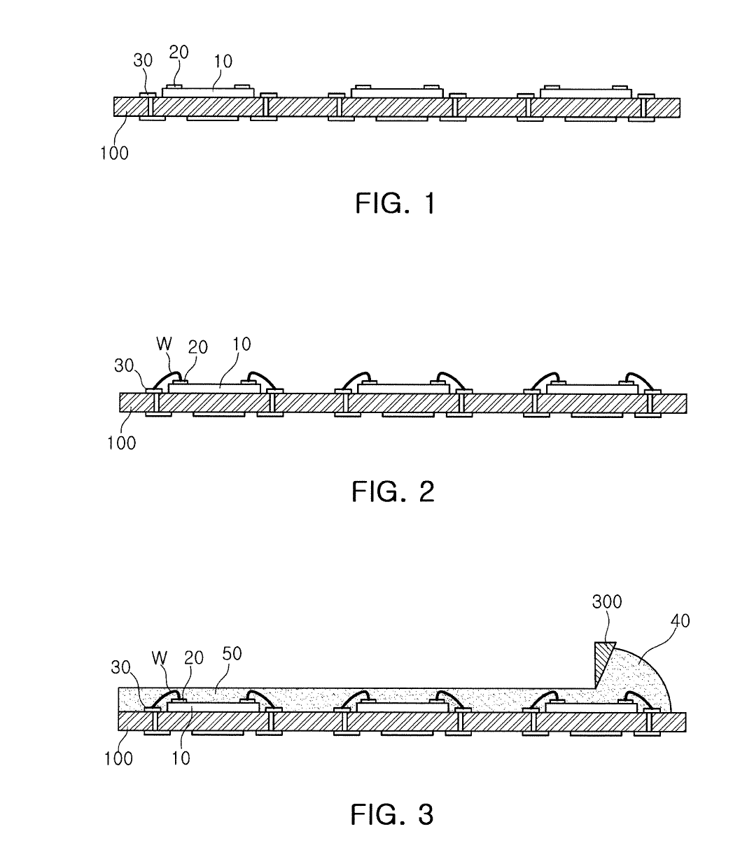

A method for manufacturing a light emitting apparatus according to an example of the present application will be described with reference to FIGS. 1 through 7.

FIG. 1 is a view schematically illustrating a step of mounting a plurality of light emitting elements 10 on a substrate.

As shown in FIG. 1, a plurality of light emitting elements 10 are mounted on a substrate 100.

The substrate 100 may include any substrate having a planar shape, such as a silicon (Si) wafer, a ceramic wafer, a metal-core printed circuit board (MCPCB), and the like, on which electrodes 30 are formed or electrodes are separated to allow a light emitting element to be mounted on the substrate.

The light emitting element 10 is a type of semiconductor device outputting light having a certain wavelength according to an electrical signal applied externally, and may include a light emitting diode (LED) chip. The light emitting element 10 may output blue light, red light, or green light according to a material contained therein, and may also output white light.

The light emitting elements 10 include an electrode pad 20 formed on an upper surface thereof to receive an external electrical signal and includes a bare chip, without a wavelength conversion unit, formed on a surface thereof, respectively. The electrode pad 20 may be, for example, a plurality of P type electrodes and N type electrodes.

The light emitting elements 10 may be disposed to be spaced apart from one another at predetermined intervals, and a plurality of light emitting elements 10 may be arranged in a column direction and a row direction on the substrate 100, forming a matrix structure.

Next, as shown in FIG. 2, electrode pads 20 formed on upper surfaces of the plurality of light emitting elements 10 are connected to the electrodes 30 formed on the substrate 100 by wires (W).

Then, as shown in FIG. 3, a resin 40 containing one or more types of phosphors is applied to form a wavelength conversion unit 50 integrally covering the plurality of light emitting elements 10 on the substrate 100.

In detail, a certain amount of the resin 40 containing phosphors is injected onto the substrate 100 through a dispenser (not shown), or the like. The resin 40 may be injected in a sufficient amount to entirely cover the plurality of light emitting elements 10.

In a state in which the resin 40 is injected, the resin 40 is pushed from one end of the substrate 100 to the other end thereof by using a tool, such as a squeegee 300, or the like, so as to be commonly applied to cover the respective light emitting elements 10 in a printed manner.

When the resin 40 containing phosphors is commonly applied to the plurality of light emitting elements 10 through a printing method through a single process, the process time is advantageously shortened. Also, since the wavelength conversion unit 50, having substantially the same characteristics, can be commonly formed, a production yield can be enhanced. Also, the wavelength conversion unit 50 may be formed to have a substantially uniform height.

In an example of the present application, the scheme of forming the wavelength conversion unit 50 through a printing method is described. However, the wavelength conversion unit 50 may also be formed by using various other methods such as spray coating, electrophoresis, and the like.

Here, the wavelength conversion unit 50 converts a wavelength of light radiated from the light emitting element 10 into a wavelength of light having a desired color. For example, the wavelength conversion unit 50 converts monochromatic light such as red light or blue light into white light. To this end, the resin 40 used to form the wavelength conversion unit 50 may contain one or more types of phosphors. Also, the wavelength conversion unit 50 may also contain an ultraviolet ray absorbent material absorbing ultraviolet rays generated by the light emitting element 10.

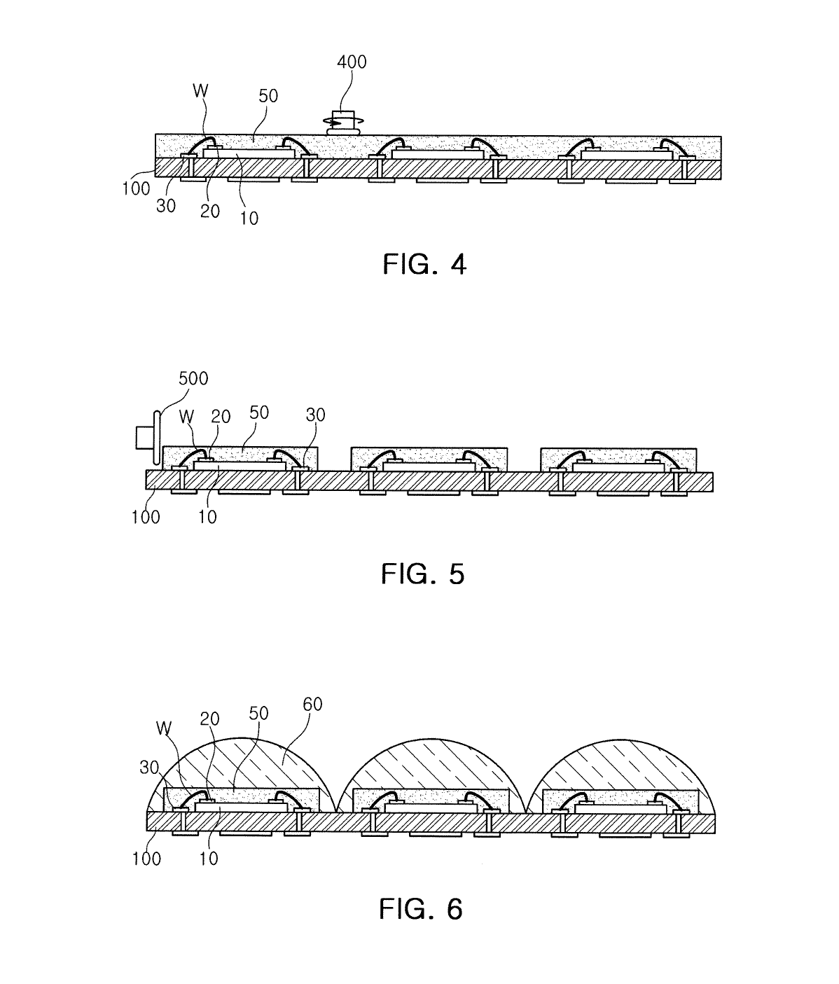

Thereafter, as shown in FIG. 4, a process of polishing an upper surface of the wavelength conversion unit formed on the light emitting elements 10 by using a polishing device 400, or the like, may be additionally performed. However, the polishing process may be omitted. Through the polishing process, the upper surface of the wavelength conversion unit 50 may be planarized.

The substrate 100 may be coated with the wavelength conversion unit 50 such that it covers the light emitting elements 10 and is then cured. The wavelength conversion unit 50 may be formed by using a resin having high transparency, capable of allowing light generated from the light emitting elements to pass therethrough with a minimum amount of loss. For example, the wavelength conversion unit 50 may be made of an elastic resin. The elastic resin, a gel type resin such as silicon, or the like, has low possibility of change such as yellowing or the like, by light having a short wavelength. In addition, the elastic resin has a high reflective index, such that it may have superior optical characteristics. Also, since even after the curing operation, the gel or elastomer state is maintained, the light emitting elements may be more stably protected against thermal stress, vibrations, external impacts, and the like. Also, the wavelength conversion unit 50 is applied in a gel state and then cured, so internal air bubbles formed in the process of curing are readily exposed to the air so as to be removed advantageously.

Next, as shown in FIG. 5, the wavelength conversion unit 50 formed between the plurality of light emitting elements 10 on the substrate 100 is removed by using a removing device such as laser, a blade groover, or the like, to separate the respective light emitting elements 10.

Thereafter, as shown in FIG. 6, lenses 60 may be additionally formed above the plurality of light emitting elements 10 having the wavelength conversion units 50 formed thereon, as necessary. The lenses 60 serve to collect or distribute light emitted from the light emitting elements 10.

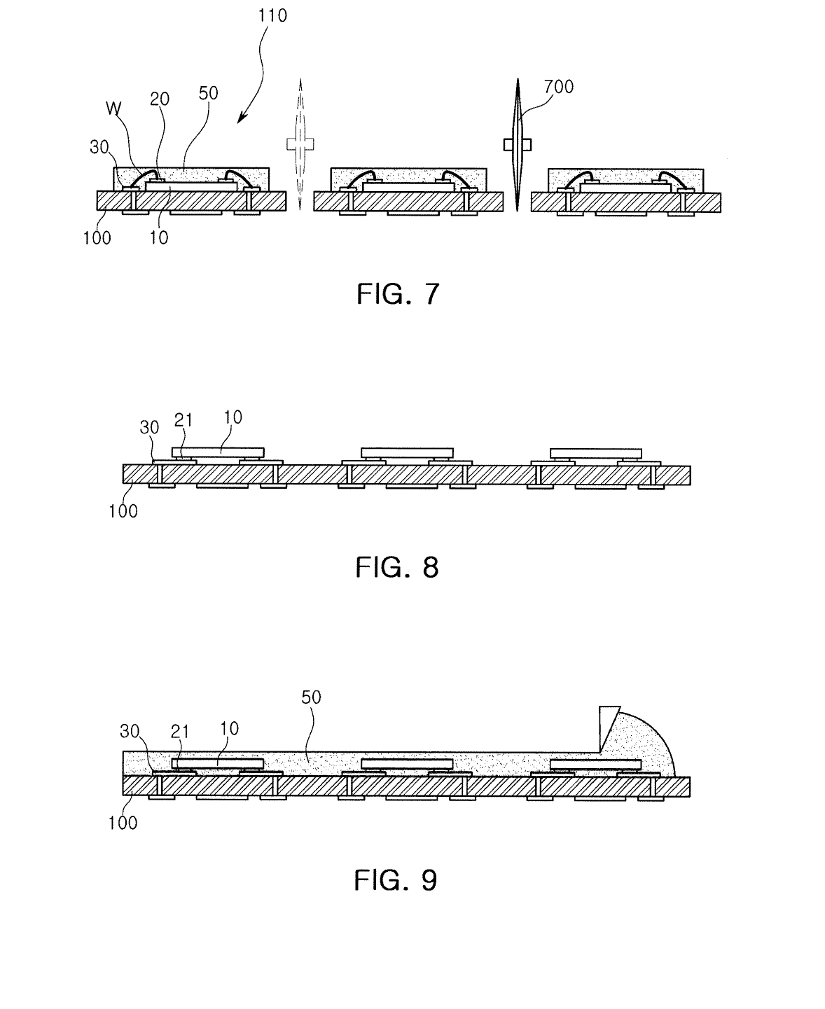

Further, as shown in FIG. 7, the plurality of light emitting elements having the wavelength conversion units 50 formed thereon are diced to be separated into individual light emitting elements.

In detail, based on the respective light emitting element 10, the substrate 100 is diced between the respective light emitting elements 10 with a cutting device 700 so as to be separated into individual light emitting elements.

Then, light emitting apparatuses 110 in which the wavelength conversion unit 50 is formed on upper and lateral surfaces of the light emitting elements 10 are manufactured.

Thus, the light emitting apparatuses 110 in which the wavelength conversion unit 50 is formed on the upper and lateral surfaces of the light emitting elements 10 can be mass-produced. Also, even light emitted from the lateral side of the light emitting element having a horizontal structure is also wavelength-converted by the wavelength conversion unit 50, light emitted from the light emitting apparatus can be wavelength-converted without a loss of light, achieving an effect of enhancing luminance efficiency.

Also, since the thickness (or height) of the wavelength conversion unit 50 of the plurality of mass-produced light emitting apparatuses is substantially uniform, so a height dispersion of the wavelength conversion unit 50 can be maintained to be uniform. Accordingly, a defect generation rate can be minimized, enhancing productivity.

A method for manufacturing a light emitting apparatus according to another example of the present application will be described with reference to FIGS. 8 through 13.

A method for manufacturing a light emitting apparatus according to another example of the present application is the same as that of the former example of the present application, except that the manufactured light emitting apparatus includes a flip-chip type light emitting element. Thus, in describing the method for manufacturing a light emitting apparatus according to another example of the present application, a repetitive description, the same as that of the method for manufacturing a light emitting apparatus according to the former example, will be omitted.

First, as shown in FIG. 8, a plurality of light emitting elements 10 are mounted on the substrate 100.

The light emitting elements 10 include an electrode pad 21 formed on an lower surface thereof to receive an external electrical signal and include a bare chip, without a wavelength conversion unit, formed on a surface thereof, respectively. The electrode pad 21 may be, for example, a plurality of P type electrodes and N type electrodes. Although not shown, the electrode pad 21 may include a solder bump.

As illustrated, the electrode pad 21 is formed on a lower surface of the light emitting element 10 and is in contact with the electrode 30 of the substrate 100, and a plurality of light emitting elements having such a structure are disposed on the substrate 100. The light emitting elements 10 may be disposed to be spaced apart from one another at predetermined intervals, and a plurality of light emitting elements 10 may be arranged in a column direction and a row direction on the substrate 100, forming a matrix structure.

As shown next in FIG. 9, the resin 40 containing one or more types of phosphors is applied to form a wavelength conversion unit 50 integrally covering the plurality of light emitting elements 10 on the substrate 100.

A certain amount of the resin 40 containing phosphors is injected onto the substrate 100 through a dispenser (not shown), or the like, and then, pushed from one end of the substrate 100 to the other end thereof by a tool such as a squeegee 300, or the like, so as to be commonly applied to the respective light emitting elements 10 in a printed manner.

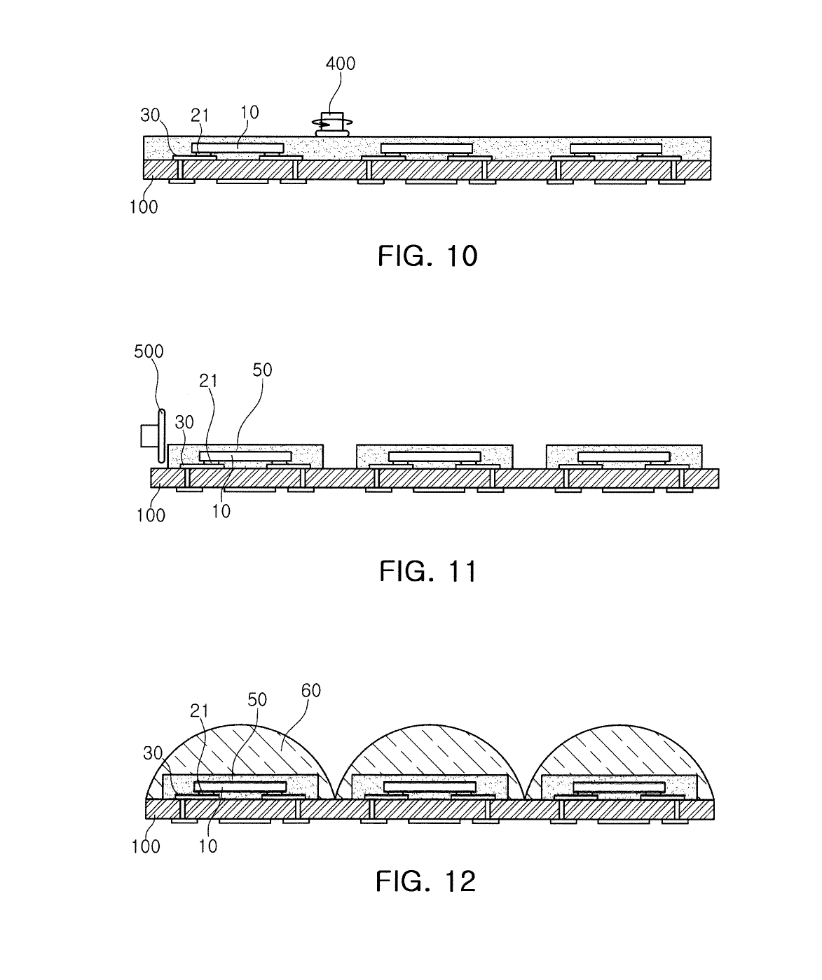

Thereafter, as shown in FIG. 10, a process of polishing an upper surface of the wavelength conversion unit 50 formed on the light emitting elements 10 by using the polishing device 400, or the like, may be additionally performed. However, the polishing process may be omitted.

The substrate 100 may be coated with the wavelength conversion unit 50 such that it covers the light emitting elements 10 and is then cured.

Then, as shown in FIG. 11, the wavelength conversion unit 50 formed between the plurality of light emitting elements 10 on the substrate 100 is removed by using a removing device 500 such as laser, a blade groover, or the like, to separate the respective light emitting elements 10.

Thereafter, as shown in FIG. 12, lenses 60 may additionally be formed above the plurality of light emitting elements 10 having the wavelength conversion units 50 formed thereon, as necessary.

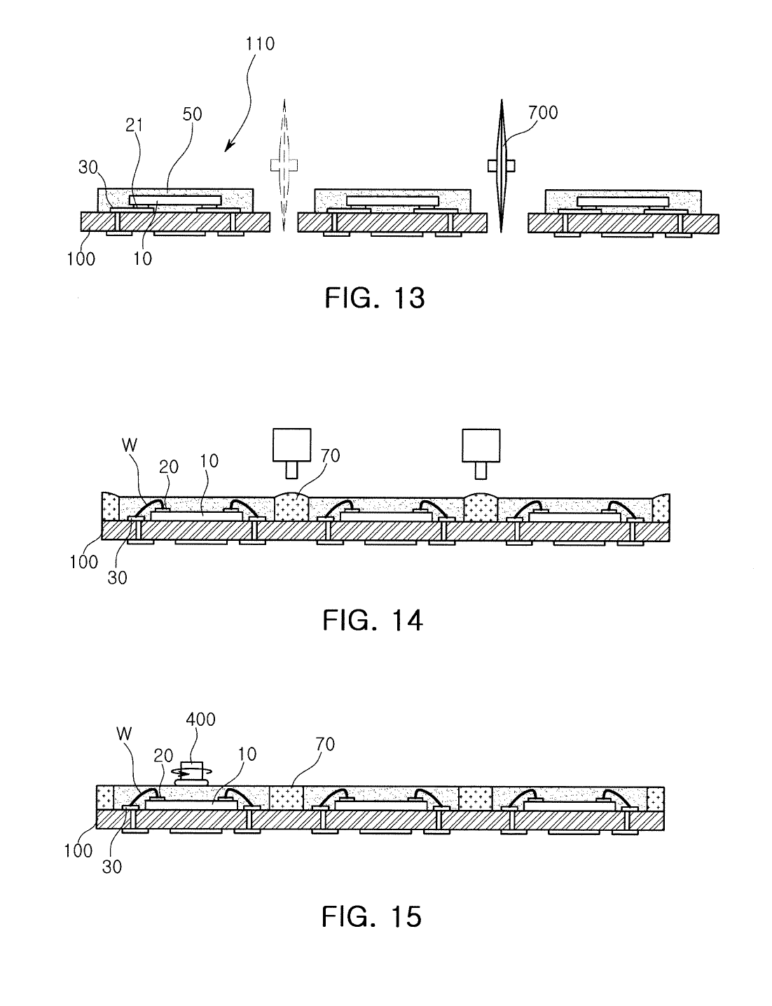

Then, as shown in FIG. 13, the plurality of light emitting elements having the wavelength conversion units 50 formed thereon are diced by using the cutting device 700 so as to be separated into individual light emitting elements. Then, light emitting apparatuses 110 in which the wavelength conversion unit 50 is formed on upper and lateral surfaces of the light emitting elements 10 are manufactured.

A method for manufacturing a light emitting apparatus according to another example of the present application will be described with reference to FIGS. 14 through 17.

First, the method for manufacturing a light emitting apparatus according to another example of the present application includes the same steps as those illustrated in FIGS. 1 through 5.

Namely, a plurality of light emitting elements 10 are mounted on a substrate 100 and electrically connected to electrodes 30 of the substrate with wires W, or the electrodes 30 of the substrate and electrode pads 20 of the light emitting elements 10 may be directly connected, a resin may be applied to form wavelength conversion units 50 covering the plurality of light emitting elements 10, an upper surface of the wavelength conversion unit 50 made of the resin 40 is planarized, and then, the wavelength conversion unit 50 between the respective light emitting elements 10 is removed to separate the respective light emitting elements 10.

Then, as shown in FIG. 14, a white resin is coated on the regions of the substrate, from which the wavelength conversion unit 50 has been removed by using the removing device 500 such as a laser, a blade groover, or the like, to form partition walls 70. Here, the white resin may be a resin including polyphthalamide (PPA), a liquid crystal polymer (LCP), polycarbonate (PC), bismaleimide trizine (BT), silicon, and the like. Also, the partition walls 70 may be variably formed according to the shape of the regions formed as the wavelength conversion unit 50 was removed.

Subsequently, as shown in FIG. 15, a process of polishing the upper surfaces of the wavelength conversion unit 50 formed on the light emitting elements 10 and the partition walls 70 by using the polishing device 400, or the like, may be additionally performed. Accordingly, the upper surfaces of the wavelength conversion unit 50 and the partition walls 70 may be planarized.

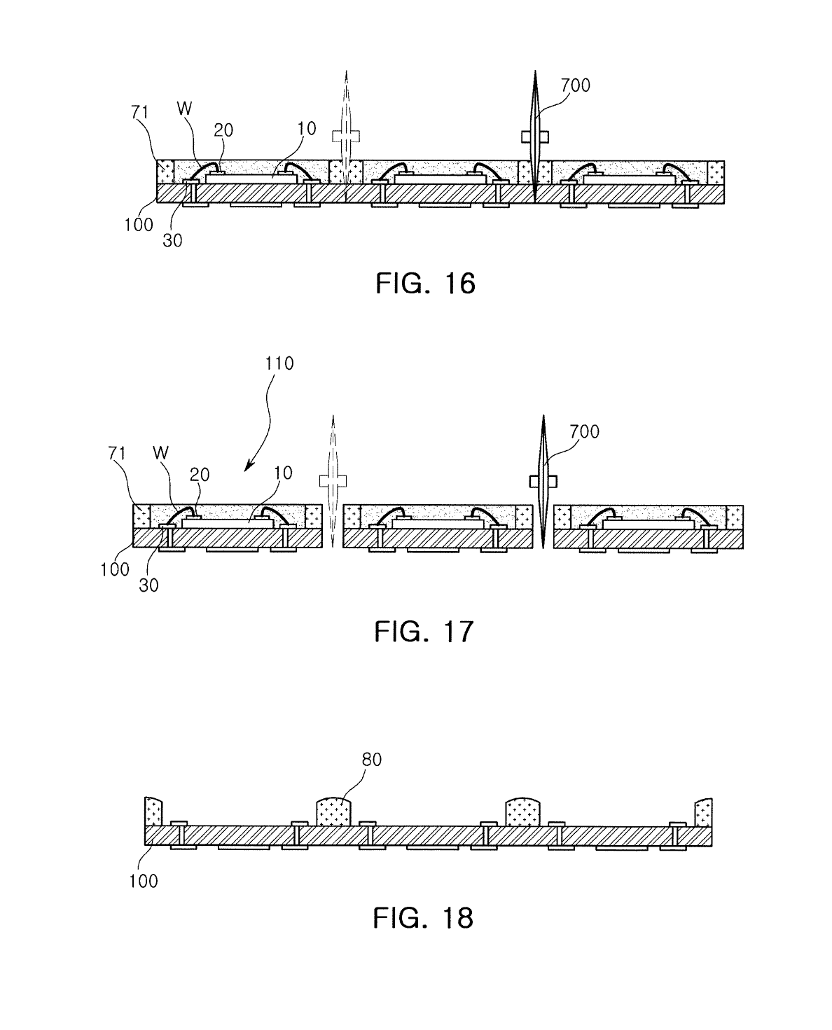

Thereafter, as shown in FIG. 16, the plurality of light emitting elements 10 having the wavelength conversion units 50 formed thereon are diced so as to be separated into individual light emitting elements.

In detail, based on the respective light emitting element 10, the partition walls 70 between the respective light emitting elements 10 and the substrate 100 under the partition walls 70 are diced by using a cutting device 700 so as to be separated into individual light emitting elements.

When a plurality of light emitting elements are separated into individual elements, the light emitting apparatus 110 including a lateral partition wall 71 is formed.

Although not shown, a lens may be formed on an upper surface of the light emitting element 10, and in the present example, a light emitting element having a horizontal structure has been described, but the present application is not limited thereto and a light emitting apparatus including a light emitting element having a flip chip structure may also be manufactured by using the manufacturing method according to the present example.

A method for manufacturing a light emitting apparatus according to another example of the present application will be described with reference to FIGS. 18 through 22.

First, as illustrated in FIG. 18, a separating partition wall 80 is formed on the substrate 100. The separating partition wall 80 may be formed by using a photosensitive polymer. Namely, a photosensitive polymer is coated on the entire surface of the substrate 100, and then, photolithography is performed thereon such that the photosensitive polymer in regions in which the separating partition wall 80 is to be formed remains and the photosensitive polymer on all the other regions is removed. Also, the separating partition wall 80 may be formed by using a dry film laminate (DFL) method. However, the present application is not limited thereto.

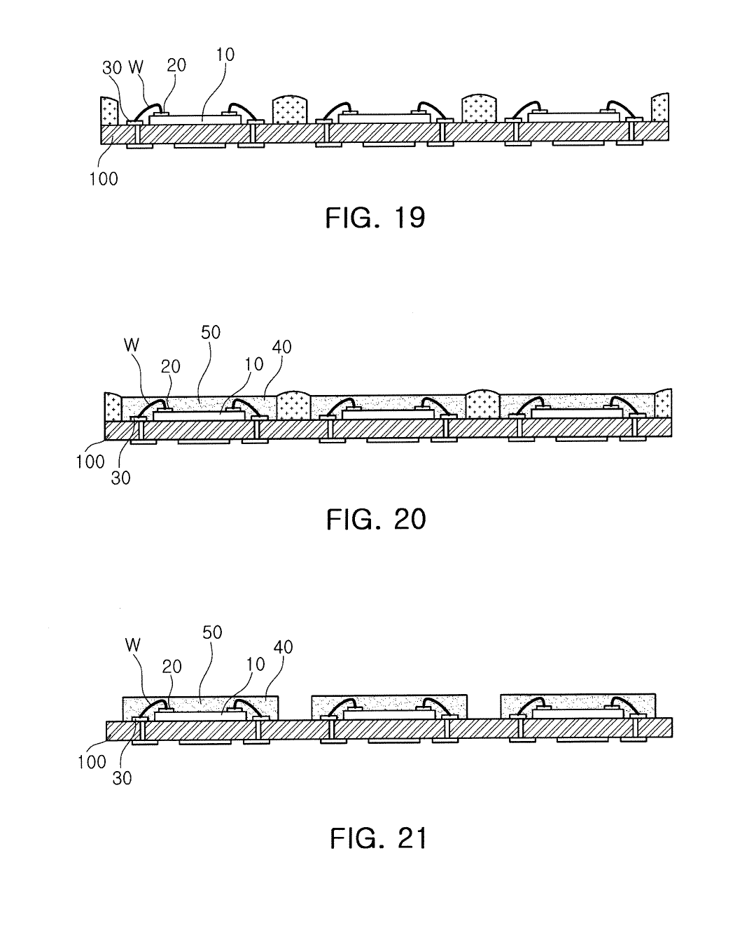

Next, as shown in FIG. 19, a plurality of light emitting elements 10 are mounted on the substrate 100 with the separating partition walls 80 formed thereon, and the electrode pads 20 formed on upper surfaces of the plurality of light emitting elements 10 are connected to the electrodes 30 formed on the substrate 100 with wires (W). However, when the light emitting elements 10 are flip chip type elements, lower surfaces of the plurality of light emitting elements 10 having electrode pads formed thereon may be disposed on the substrate 100 such that they are in contact with the electrodes 30 of the substrate 100.

Then, as shown in FIG. 20, the resin 40 containing one or more types of phosphors is applied to regions between the separating partition walls 80 to form wavelength conversion units 50 covering the light emitting elements 10 on the substrate 100.

In detail, a certain amount of the resin 40 containing phosphors is injected onto the substrate 100 through a dispenser (not shown), or the like.

Here, a process of polishing an upper surface of the wavelength conversion units 50 formed on the light emitting elements 10 by using the polishing device 400, or the like, may additionally be performed. Through the polishing process, the upper surfaces of the wavelength conversion units 50 are planarized.

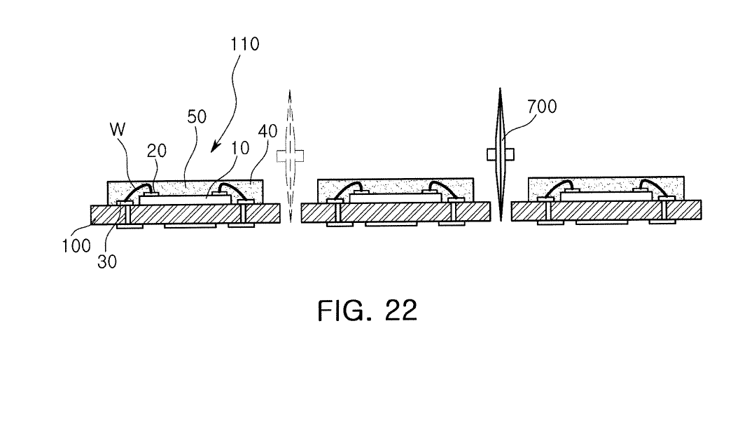

Thereafter, as shown in FIG. 21, the separating partition walls 80 formed between the plurality of light emitting elements 10 formed on the substrate 100 are removed to separate the respective light emitting elements 10.

Then, a lens may be additionally formed.

Thereafter, as shown in FIG. 22, the plurality of light emitting elements 10 are diced so as to be separated into individual light emitting elements.

In detail, the substrate 100 positioned at the regions between the light emitting elements 10, from which the separating partition walls 80 was removed, is diced by using the cutting device 700 so as to be separated into individual light emitting elements. Then, the light emitting apparatuses 110 in which the wavelength conversion units 50 are formed on upper and lateral surfaces of the light emitting elements can be manufactured.

As set forth above, according to examples of the application, in manufacturing a light emitting element having a horizontal structure and a flip chip type light emitting element, a wavelength conversion material is applied to an upper portion of the light emitting element in the wafer unit (or on the wafer level) to thereby form a light emitting apparatus in which a wavelength conversion unit has a uniform height overall, and accordingly, a defect generation rate can be minimized and productivity can be enhanced. Also, since the wavelength conversion material is coated on the upper portion of the light emitting element in the wafer unit, the process is simplified.

While the foregoing has described what are considered to be the best mode and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

What is claimed is:

1. A method for manufacturing a light emitting apparatus, the method comprising steps of:
mounting a plurality of light emitting elements on a substrate;
applying a resin containing phosphors to form wavelength conversion units covering the plurality of light emitting elements on the substrate;
removing portions of the wavelength conversion unit between the plurality of light emitting elements; and
dicing regions of the substrate, from which the portions of the wavelength conversion unit have been removed, to separate the plurality of light emitting elements into individual light emitting elements.

2. The method of claim 1, wherein the step of mounting the plurality of light emitting elements comprises:
connecting electrode pads formed on upper surfaces of the plurality of light emitting elements to electrodes formed on the substrate with wires.

3. The method of claim 1, wherein the step of mounting the plurality of light emitting elements comprises:
mounting the plurality of light emitting elements on the substrate such that lower surfaces thereof having the electrode pads formed thereon are in contact with the electrodes of the substrate.

4. The method of claim 1, wherein the step of forming of the wavelength conversion unit includes:
commonly applying a resin containing one or more types of phosphors to the plurality of light emitting elements by way of a printing process.

5. The method of claim 1, wherein the step of removing the portions of the wavelength conversion unit includes:
removing the wavelength conversion unit by way of a laser lift-off process or blade grooving.

6. The method of claim 1, further comprising the step of:
after removing the wavelength conversion unit formed between the plurality of light emitting elements, forming lenses on upper surfaces of the plurality of light emitting elements having the wavelength conversion unit formed thereon.

7. A method for manufacturing a light emitting apparatus, the method comprising steps of:
mounting a plurality of light emitting elements on a substrate;
applying a resin containing phosphors to form wavelength conversion units covering the plurality of light emitting elements on the substrate;
removing portions of the wavelength conversion unit between the plurality of light emitting elements;
filling upper portions of the substrate, from which the wavelength conversion unit have been removed, with a resin to form partition walls; and
dicing the partition walls and the substrate under the partition walls to separate the plurality of light emitting elements into individual light emitting elements.

8. The method of claim 7, wherein the step of mounting the plurality of light emitting elements comprises:
connecting electrode pads formed on upper surfaces of the plurality of light emitting elements to electrodes formed on the substrate with wires.

9. The method of claim 7, wherein the step of mounting the plurality of light emitting elements comprises:
mounting the plurality of light emitting elements on the substrate such that lower surfaces thereof having the electrode pads formed thereon are in contact with the electrodes of the substrate.

10. The method of claim 7, wherein the step of forming of the wavelength conversion unit includes:
commonly applying a resin containing one or more types of phosphors to the plurality of light emitting elements by way of a printing process.

11. The method of claim 7, wherein the step of removing the portions of the wavelength conversion unit includes:
removing the wavelength conversion unit by way of a laser lift-off process or blade grooving

12. The method of claim 7, wherein the resin includes one or more materials among polyphthalamide (PPA), a liquid crystal polymer (LOP), polycarbonate (PC), bismaleimide trizine (BT), and silicon.

13. The method of claim 7, further comprising the step of:
polishing upper surfaces of the wavelength conversion unit and the partition walls, after the forming of the partition walls by filling the upper portions of the substrate, from which the wavelength conversion unit have been removed, with the resin.

14. A method for manufacturing a light emitting apparatus, the method comprising steps of:
forming partition walls confining peripheral regions of light emitting elements on mounting portions in which the light emitting elements are to be mounted on a substrate;
mounting a plurality of light emitting elements on the mounting portions;
applying a resin containing one or more phosphors to inner sides of the partition walls to form wavelength conversion units covering the plurality of light emitting elements;
removing the partition walls; and
dicing the portions of the substrate, from which the partition walls were removed, to separate the plurality of light emitting elements into individual light emitting elements.

15. The method of claim 14, wherein the step of mounting the plurality of light emitting elements comprises:
connecting electrode pads formed on upper surfaces of the plurality of light emitting elements to electrodes formed on the substrate with wires.

16. The method of claim 14, wherein the step of mounting the plurality of light emitting elements comprises:
mounting the plurality of light emitting elements on the substrate such that lower surfaces thereof having the electrode pads formed thereon are in contact with the electrodes of the substrate.

17. The method of claim 14, wherein the step of forming the partition walls comprises:
coating the substrate with a photosensitive polymer and then performing photolithography thereon.

18. The method of claim 14, wherein the step of forming the partition walls includes:
forming the partition walls by way of a dry film laminate (DFL) process.

19. The method of claim 14, further comprising the step of:
after removing the partition walls, forming lenses on upper surfaces of the light emitting elements having the wavelength conversion unit formed thereon.

20. A light emitting apparatus comprising:
a substrate;
light emitting elements mounted on the substrate; and
a wavelength conversion unit formed on upper and lateral surfaces of the plurality of light emitting elements and converting a wavelength of light emitted from the light emitting elements.
